(19) United States
(12) Patent Application Publication
(10) Pub. No.: US 2025/0063900 A1
(43) Pub. Date: Feb. 20, 2025

(54) DISPLAY PANEL AND PRODUCTION METHOD AND DISPLAY APPARATUS

(71) Applicants: Chengdu BOE Optoelectronics Technology Co., Ltd., Sichuan (CN); BOE TECHNOLOGY GROUP CO., LTD., Beijing (CN)

(72) Inventors: De LI, Beijing (CN); Wenbo CHEN, Beijing (CN); Tiaomei ZHANG, Beijing (CN); Haigang QING, Beijing (CN); Quanyong GU, Beijing (CN); Mengqi WANG, Beijing (CN)

(21) Appl. No.: 18/722,686

(22) PCT Filed: Dec. 28, 2021
(86) PCT No.: PCT/CN2021/142189

§ 371 Date: Jun. 21, 2024

(51) Int. Cl. H10K 59/123; H10K 59/00; H10K 59/122; H10K 59/124; H10K 59/131; H10K 59/80

(52) U.S. Cl. CPC H10K 59/123; H10K 59/122; H10K 59/124; H10K 59/131; H10K 59/751; H10K 59/8051; H10K 59/87

(57) ABSTRACT

Provided are a display panel, a manufacturing method, and a display device. The display panel includes: a substrate including a display area and a peripheral area; a driving circuit layer including: a pixel circuit in the display area, and a gate driver circuit on a side of the pixel circuit in proximity to the peripheral area, and at least partially in the display area; a first metal layer on a side of the driving circuit layer away from the substrate, insulated from the driving circuit layer; and a first electrode layer in the display area and on a side of the first metal layer away from the substrate, insulated from the first metal layer, and electrically connected to the pixel circuit; where orthographic projections, on the substrate, of the first electrode layer, the first metal layer, and the gate driver circuit, are at least partially overlapped.

### CROSS-REFERENCE TO RELATED APPLICATION

The present application is a U.S. national phase application of International Application No. PCT/CN2021/142189, filed on Dec. 28, 2021, the entire contents of which are hereby incorporated by reference in its entirety.

### TECHNICAL FIELD

The present disclosure relates to the field of display technology, and in particular, to a display panel, a method for manufacturing a display panel, and a display device.

### BACKGROUND

In recent years, Organic Light Emitting Diode (OLED) has become one of the hotspots in the research field of flat panel displays. More and more Active Matrix Organic Light Emitting Diode (AMOLED) display panels have entered the market. Compared to traditional Thin Film Transistor Liquid Crystal Display (TFTLCD) panels, AMOLED panels have faster response times, higher contrast, and wider viewing angles.

With the development of display technology, there are increasingly strict requirements for the border width and display effect of display devices. It is required to achieve narrower borders while ensuring the display effect of the display device. However, in the related art, there is still room for improvement in achieving narrow borders and ensuring display quality.

The information disclosed above in the “BACKGROUND” section is only used to enhance the understanding of the background of the present disclosure, and therefore, it may include information that does not constitute prior art known to those of ordinary skill in the art.

### SUMMARY

The purpose of the present disclosure is to provide a display panel that reduces the area occupied by the gate driver circuit in the peripheral area, which helps achieve a narrow border design for the display panel. The present disclosure also provides a structural basis to prevent the jittering or fluctuation of transistors inside the gate driver circuit from affecting the display effect.

To achieve the above-mentioned purpose, the present disclosure adopts the following technical solutions.

According to a first aspect of the present disclosure, a display panel is provided, including:
a substrate including a display area and a peripheral area around the display area;
a driving circuit layer on a side of the substrate, including a driving circuit, where the driving circuit includes a gate driver circuit and a pixel circuit; the pixel circuit is in the display area, and the gate driver circuit is on a side of the pixel circuit in proximity to the peripheral area, and at least partially in the display area;
a first metal layer on a side of the driving circuit layer away from the substrate, insulated from the driving circuit layer; and
a light-emitting device layer on a side of the first metal layer away from the substrate, including a first electrode layer, which is insulated from the first metal layer, in the display area, and electrically connected to the pixel circuit; where an orthographic projection of the first electrode layer on the substrate, an orthographic projection of the first metal layer on the substrate, and an orthographic projection of the gate driver circuit on the substrate, are at least partially overlapped.

In an exemplary embodiment of the present disclosure, the display area includes: a main display area, and an auxiliary display area on a side of the main display area in proximity to the peripheral area;
the pixel circuit is in the main display area, the gate driver circuit is at least partially in the auxiliary display area, and the first metal layer is at least partially in the auxiliary display area;
the pixel circuit includes a plurality of pixel circuits, the first electrode layer includes a plurality of first electrodes, each first electrode of the plurality of first electrodes includes an electrical connection portion, and each first electrode of the plurality of first electrodes is electrically connected to a corresponding pixel circuit through the electrical connection portion; and an orthographic projection, on the substrate, of the electrical connection portion of the first electrode in the auxiliary display area, is within the orthographic projection of first metal layer on the substrate.

In an exemplary embodiment of the present disclosure, the light-emitting device layer further includes a light-emitting functional layer and a second electrode layer arranged in sequence on a side of the first electrode layer away from the substrate; and
the display panel further includes:
a first power line between the substrate and the first metal layer, in the peripheral area; where
the first power line is electrically connected to the first metal layer, and the first metal layer is electrically connected to the second electrode layer.

In an exemplary embodiment of the present disclosure, the orthographic projection of the first metal layer on the substrate at least partially overlaps with an orthographic projection of the first power line on the substrate; and
an end of the first metal layer is overlapped and connected to a surface of the first power line away from the substrate.

In an exemplary embodiment of the present disclosure, the first power line is disposed in a same layer with a source and drain of a transistor in the driving circuit.

In an exemplary embodiment of the present disclosure, the display panel further includes:
a first connection layer between the first metal layer and the second electrode layer, where an orthographic projection of the first connection layer on the substrate, at least partially overlaps with the orthographic projection of the first metal layer on the substrate, and the first metal layer is electrically connected to the second electrode layer through the first connection layer.

In an exemplary embodiment of the present disclosure, the first connection layer is disposed in a same layer with the first electrode layer.

In an exemplary embodiment of the present disclosure, the display panel further includes:
a second connection layer between the first metal layer and the first connection layer, where the second connection layer is electrically connected to the first metal layer and electrically connected to the first connection layer.

In an exemplary embodiment of the present disclosure, the driving circuit layer further includes:
a light-emitting control circuit between the first power line and the gate driver circuit, where
the orthographic projection of the first metal layer on the substrate, at least partially overlaps with an orthographic projection of the light-emitting control circuit on the substrate.

In an exemplary embodiment of the present disclosure, the display panel further includes:
a first planarization layer on the side of the driving circuit layer away from the substrate, including a first segment and a second segment arranged in sequence and spaced apart,
where an orthographic projection of the first segment on the substrate, at least partially overlaps with the orthographic projection of the light-emitting control circuit on the substrate, and an overlapping area, between the orthographic projection of the first segment on the substrate and the orthographic projection of the gate driver circuit on the substrate, is zero; and
where an orthographic projection of the second segment on the substrate, at least partially overlaps with the orthographic projection of the gate driver circuit on the substrate, and an overlapping area, between the orthographic projection of the second segment on the substrate and the orthographic projection of the light-emitting control circuit on the substrate, is zero.

In an exemplary embodiment of the present disclosure, the first metal layer includes a first metal segment and a second metal segment spaced apart,
where the first metal segment at least partially covers a surface of the first segment away from the substrate, the second metal segment at least partially covers a surface of the second segment away from the substrate, and an orthographic projection of the first metal segment on the substrate and an orthographic projection of the second metal segment on the substrate, do not within a gap between the orthographic projection of the first segment on the substrate and the orthographic projection of the second segment on the substrate.

In an exemplary embodiment of the present disclosure, the first planarization layer further includes a third segment between the first segment and the second segment, with the first segment, third segment, and second segment being spaced apart from each other,
where an orthographic projection of the third segment on the substrate, is between the orthographic projection of the light-emitting control circuit on the substrate and the orthographic projection of the gate driver circuit on the substrate.

In an exemplary embodiment of the present disclosure, the display panel further includes:
a second planarization layer between the first metal layer and the first connection layer, including a fourth segment and a fifth segment arranged in sequence and spaced apart,
where an orthographic projection of the fourth segment on the substrate, at least partially overlaps with the orthographic projection of the light-emitting control circuit on the substrate, and an overlapping area, between the orthographic projection of the fourth segment on the substrate and the orthographic projection of the gate driver circuit on the substrate, is zero; and
where an orthographic projection of the fifth segment on the substrate, at least partially overlaps with the orthographic projection of the gate driver circuit on the substrate, and an overlapping area, between the orthographic projection of the fifth segment on the substrate and the orthographic projection of the light-emitting control circuit on the substrate, is zero.

In an exemplary embodiment of the present disclosure, when the display panel further includes a second connection layer, the second planarization layer is between the first metal layer and the second connection layer;
the display panel further includes:
a third planarization layer between the second connection layer and the first connection layer, including a sixth segment and a seventh segment arranged in sequence and spaced apart,
where an orthographic projection of the sixth segment on the substrate, at least partially overlaps with the orthographic projection of the light-emitting control circuit on the substrate, and an overlapping area, between the orthographic projection of the sixth segment on the substrate and the orthographic projection of the gate driver circuit on the substrate, is zero; and
where an orthographic projection of the seventh segment on the substrate, at least partially overlaps with the orthographic projection of the gate driver circuit on the substrate, and an overlapping area, between the orthographic projection of the seventh segment on the substrate and the orthographic projection of the light-emitting control circuit on the substrate, is zero.

In an exemplary embodiment of the present disclosure, when the display panel further includes the second connection layer, the second connection layer includes a first connection segment and a second connection segment spaced apart,
where the first connection segment at least partially covers a surface of the sixth segment away from the substrate, the second connection segment at least partially covers a surface of the seventh segment away from the substrate, and an orthographic projection of the first connection segment on the substrate and an orthographic projection of the second connection segment on the substrate, do not within a gap between the orthographic projection of the sixth segment on the substrate and the orthographic projection of the seventh segment on the substrate.

In an exemplary embodiment of the present disclosure, the driving circuit layer includes:
an active layer on a side of the substrate;
a first gate insulation layer on a side of the active layer away from the substrate, covering the active layer;
a first gate metal layer on a side of the first gate insulation layer away from the substrate, configured to form a first electrode plate of a capacitor in the driving circuit, and a gate of a transistor in the driving circuit;
a second gate insulation layer on a side of the first gate metal layer away from the substrate, covering the first gate metal layer;
a second gate metal layer on the side of the first gate insulation layer away from the substrate, disposed opposite to the first electrode plate, and configured to form a second electrode plate of the capacitor in the driving circuit;
an interlayer dielectric layer on a side of the second gate metal layer away from the substrate, covering the second gate metal layer; and
a first source and drain layer on a side of the interlayer dielectric layer away from the substrate, configured to form a source and drain of the transistor in the driving circuit, with the source and drain connected to the active layer.

In an exemplary embodiment of the present disclosure, the display panel further includes:
a passivation layer between the driving circuit layer and the first planarization layer; and
a second source and drain layer on a side of the first planarization layer away from the substrate;
where the first metal layer is disposed in a same layer with the second source and drain layer.

According to a second aspect of the present disclosure, a method for manufacturing a display panel is provided, including:
providing a substrate including a display area and a peripheral area around the display area;
forming a driving circuit layer on a side of the substrate, including a driving circuit, where the driving circuit includes a gate driver circuit and a pixel circuit; the pixel circuit is in the display area; and the gate driver circuit is on a side of the pixel circuit in proximity to the peripheral area, and at least partially in the display area;
forming a first metal layer on a side of the driving circuit layer away from the substrate, the first metal layer being insulated from the driving circuit layer; and
forming a first electrode layer on a side of the first metal layer away from the substrate, the first electrode layer being insulated from the first metal layer, in the display area, and electrically connected to the pixel circuit, where an orthographic projection of the first electrode layer on the substrate, an orthographic projection of the first metal layer on the substrate, and an orthographic projection of the gate driver circuit on the substrate, are at least partially overlapped.

According to a third aspect of the present disclosure, a display device is provided, including the display panel of the first aspect.

In the display panel provided in the present disclosure, the gate driver circuit is at least partially provided in the display area, reducing the area occupied by the gate driver circuit in the peripheral area, thereby facilitating the achievement of a narrow border design for the display panel. Additionally, the display panel in the present disclosure also includes a first metal layer located between the gate driver circuit and the first electrode layer, providing a structural basis to prevent jittering or fluctuation of transistors inside the gate driver circuit from affecting the display effect.

### BRIEF DESCRIPTION OF THE DRAWINGS

The figures described herein are incorporated into the specification and form part of the specification, which show embodiments in accordance with the present disclosure and are used in conjunction with the specification to explain the principles of the present disclosure. Obviously, the figures described below are merely some of embodiments of the present disclosure, and those of ordinary skill in the art can obtain other figures based on these figures without creative labor.

FIG. 1 is an equivalent circuit diagram of a pixel circuit according to an exemplary embodiment of the present disclosure.

FIG. 2 is a schematic diagram of a distribution structure of various circuits in a driving circuit according to an exemplary embodiment of the present disclosure.

FIG. 3 is a schematic diagram of a structure of a driving circuit layer and a light-emitting device layer in a display panel according to an exemplary embodiment of the present disclosure.

FIG. 4 is a schematic diagram of a structure of a display panel including a gate driver circuit area according to an exemplary embodiment of the present disclosure.

FIG. 5 is a schematic diagram of a structure of a display panel including a gate driver circuit area according to another exemplary embodiment of the present disclosure.

FIG. 6 is a schematic diagram of a structure of a display panel including a gate driver circuit area according to yet another exemplary embodiment of the present disclosure.

FIG. 7 is a schematic diagram of a structure of a display panel including a gate driver circuit area according to yet another exemplary embodiment of the present disclosure.

FIG. 8 is a schematic diagram of a layout structure of a pixel circuit according to an exemplary embodiment of the present disclosure.

FIG. 9 is a schematic diagram of a structure of a first connection layer and a first electrode layer according to an exemplary embodiment of the present disclosure.

FIG. 10 is a schematic diagram of a structure of a first metal layer and a second source and drain layer according to an exemplary embodiment of the present disclosure.

Reference numerals of main components in the figures are explained as follows.

1—Substrate; 11—Display area; 111—Main display area; 1111—Central area; 1112—Edge area; 112—Auxiliary display area; 12—Peripheral area; 2—Driving circuit layer; 200—Pixel circuit; 201—Gate driver circuit; 202—Light-emitting control circuit; L—First power line; 21—Active layer; 22—First gate insulation layer; 23—First gate metal layer; 24—Second gate insulation layer; 25—Second gate metal layer; 26—Interlayer dielectric layer; 27—First source and drain layer; 3—Passivation layer; 4—First planarization layer; 41—First segment; 42—Second segment; 43—Third segment; 50—First metal layer; 501—First metal segment; 502—Second metal segment; 51—Second source and drain layer; 6—Second planarization layer; 61—Fourth segment; 62—Fifth segment; 70—Second connection layer; 701—First connection segment; 702—Second connection segment; 71—Conductive layer; 8—Third planarization layer; 81—Sixth segment; 82—Seventh segment; 90—First connection layer; 91—First electrode layer; 911—First electrode; 911a—Electrical connection portion; 92—Light-emitting functional layer; 93—Second electrode layer; 900—Light-emitting device layer; 901—Light-emitting device; 10—Pixel definition layer.

### DETAILED DESCRIPTION

Exemplary embodiments will be described more comprehensively with reference to the accompanying drawings herein. However, the exemplary embodiments can be implemented in various forms and should not be construed as limited to the embodiments disclosed herein; instead, these embodiments are provided to fully and completely convey the concept of the exemplary embodiments to those skilled in the art. The same reference numerals in the figures represent the same or similar structures, and therefore detailed descriptions of them are omitted. In addition, the drawings are illustrative and not necessarily drawn to scale in this disclosure.

Although relative terms such as “above” and “below” are used in this specification to describe the relative position of one component of a marker to another, these terms are used for convenience, such as based on the orientation of the examples in the figures. It can be understood that if the marked device is flipped upside down, the component described as being “above” will become the component “below”. When a structure is described as being “on” another structure, it may refer to the structure being integrally formed on the other structure, or the structure being “directly” positioned on the other structure, or the structure being “indirectly” positioned on the other structure via another structure.

The terms “a,” “an,” “the,” “said,” and “at least one” are used to indicate one or more elements/components/etc. The terms “comprising/including” and “having” are used to express an open-ended inclusion and mean including other elements/components/etc. in addition to those listed. The terms “first,” “second,” “third,” etc., are used for labeling purposes only and do not limit the quantity of respective labeled objects.

In related art, in order to reduce the width of the border of a display device, the Gate On Array (GOA) area of the gate driver circuit is typically fabricated on the outside of the display area of the array substrate and inside the encapsulation adhesive, thereby reducing the area occupied by the gate driver chip (Gate IC) and the PAD area connecting the Gate IC to the gate lines in the traditional array substrate's border area, thus achieving a reduction in the width of the border.

However, the above design has limited effectiveness in reducing the width of the border of the display device and still cannot achieve the narrow border display effect desired by users.

Therefore, in related technical solutions, some portions of the gate driver circuit on the outside of the display area are set within the display area. For example, in the OLED display device, the size of the pixel circuit beneath the light-emitting device in the display area is reduced to leave some space for setting the gate driver circuit, with the gate driver circuit partially positioned below the light-emitting device. However, in this solution, the transition of certain transistors in the gate driver circuit may cause the transition of the anode node connected to the light-emitting device, affecting normal light-emitting display.

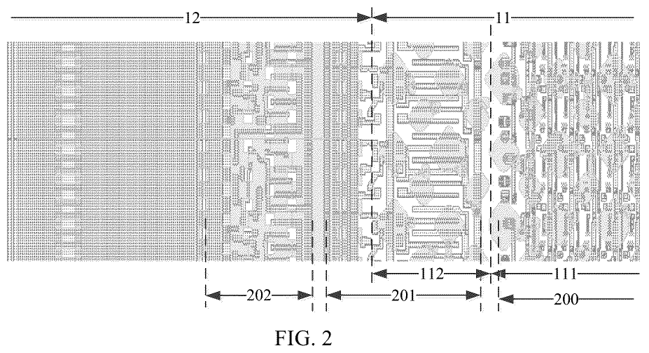

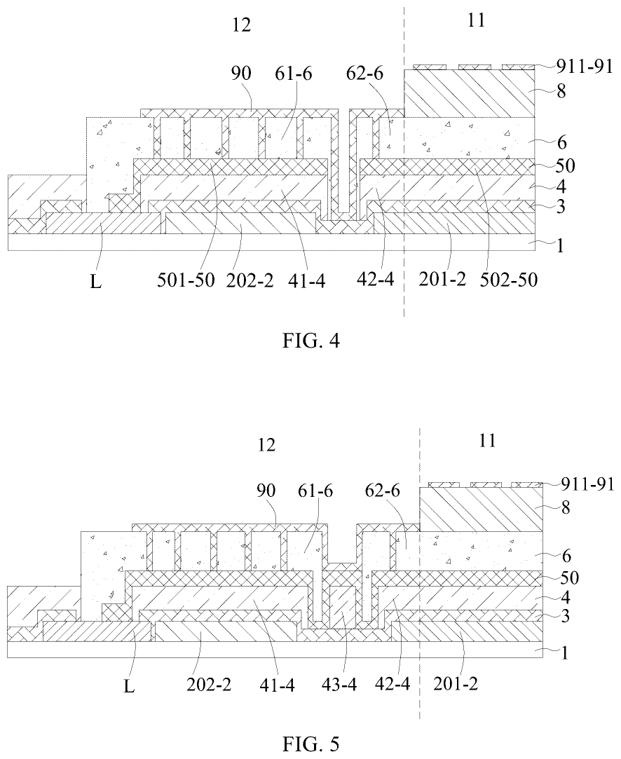

As shown in FIG. 2 and FIG. 4, in an embodiment of the present disclosure, a display panel is provided, including a substrate 1, a driving circuit layer 2, a first metal layer 50, and a light-emitting device layer 900. The substrate 1 includes a display area 11 and a peripheral area 12 set around the display area 11. The driving circuit layer 2 is disposed on a side of the substrate 1 and includes a gate driver circuit 201 and a pixel circuit 200. The pixel circuit 200 is located in the display area 11, while the gate driver circuit 201 is located on a side of the pixel circuit 200 in proximity to the peripheral area 12, and the gate driver circuit 201 is at least partially located in the display area 11. The first metal layer 50 is located on a side of the driving circuit layer 2 away from the substrate 1 and is insulated from the driving circuit layer 2. The light-emitting device layer 900 is located on a side of the first metal layer 50 away from the substrate 1 and includes a first electrode layer 91. The first electrode layer 91 is insulated from the first metal layer 50, located in the display area 11, and electrically connected to the pixel circuit 200. An orthographic projection of the first electrode layer 91 on the substrate 1, an orthographic projection of the first metal layer 50 on the substrate 1, and an orthographic projection of the gate driver circuit 201 on the substrate 1 are at least partially overlapped.

In the display panel provided in the present disclosure, the gate driver circuit 201 is at least partially provided in the display area 11, reducing the area occupied by the gate driver circuit 201 in the peripheral area 12, thereby facilitating the achievement of a narrow border design for the display panel. Additionally, the display panel in the present disclosure also includes the first metal layer 50, which is located between the gate driver circuit 201 and the first electrode layer 91, providing a structural basis to prevent jittering or fluctuation of the transistors within the gate driver circuit 201 from affecting the display effect.

The following detailed description of the components of the display panel provided in the embodiments of the present disclosure is described in conjunction with the accompanying drawings.

The embodiments of the present disclosure provide a display panel, which can be an Organic Light-Emitting Diode (OLED) display panel. The display panel includes a substrate 1, a driving circuit layer 2, a first metal layer 50, and a light-emitting device layer 900.

As shown in FIG. 2 and FIG. 4, the substrate 1 includes a display area 11 and a peripheral area 12 located around the display area 11. The display area 11 is used for displaying images. The substrate 1 can be a substrate 1 made of inorganic materials or a substrate 1 made of organic materials. For example, in one embodiment of the present disclosure, the material of the substrate 1 can be glass materials such as soda-lime glass, quartz glass, sapphire glass, or metal materials such as stainless steel, aluminum, nickel. In another embodiment of the present disclosure, the material of the substrate 1 can be Polymethyl methacrylate (PMMA), Polyvinyl alcohol (PVA), Polyvinyl phenol (PVP), Polyether sulfone (PES), polyimide, polyamide, polyacetal, Poly carbonate (PC), Polyethylene terephthalate (PET), Polyethylene naphthalate (PEN), or combinations thereof. The substrate 1 can also be a flexible substrate 1. For example, in one embodiment of the present disclosure, the material of the substrate 1 can be polyimide (PI). The substrate 1 may also be a composite of multiple materials, for example, in one embodiment of the present disclosure, the substrate 1 may include a bottom film layer, a pressure-sensitive adhesive layer, a first polyimide layer, and a second polyimide layer stacked in sequence.

The driving circuit layer 2 is located on a side of the substrate 1 and includes a driving circuit. The driving circuit includes a gate driver circuit 201 and a pixel circuit 200. The pixel circuit 200 is located within the display area 11 and is used to drive the light-emitting devices of the OLED display panel to emit light. The pixel circuit 200 can be a 7T1C, 7T2C, 6T1C, or 6T2C circuit, without specific structural limitations. Here, nTmC represents a pixel circuit 200 including n transistors (represented by the letter “T”) and m capacitors (represented by the letter “C”).

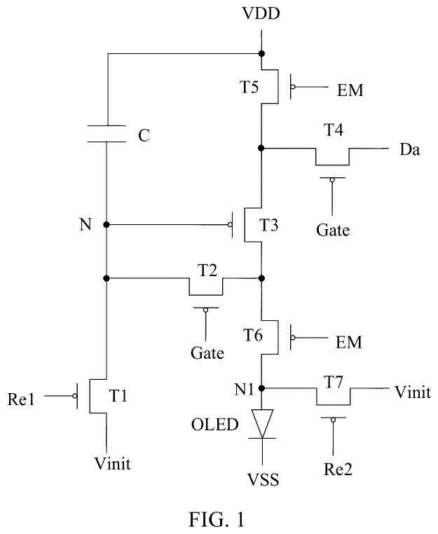

As shown in FIG. 1, in some embodiments of the present disclosure, the pixel circuit 200 is a 7T1C circuit. The pixel circuit 200 may include: a first transistor T1, a second transistor T2, a driving transistor T3, a fourth transistor T4, a fifth transistor T5, a sixth transistor T6, a seventh transistor T7, and a capacitor C. A first electrode of the first transistor T1 is connected to node N, a second electrode of the first transistor T1 is connected to an initial signal terminal Vinit, and a gate of the first transistor T1 is connected to a reset signal terminal Re1. A first electrode of the second transistor T2 is connected to a first electrode of the driving transistor T3, a second electrode of the second transistor T2 is connected to node N, and a gate of the second transistor T2 is connected to a gate driving signal terminal Gate. A gate of the driving transistor T3 is connected to node N. A first electrode of the fourth transistor T4 is connected to a data signal terminal Da, a second electrode of the fourth transistor T4 is connected to a second electrode of the driving transistor T3, and a gate of the fourth transistor T4 is connected to a gate driving signal terminal Gate. A first electrode of the fifth transistor T5 is connected to a first power terminal VDD, a second electrode of the fifth transistor T5 is connected to the second electrode of the driving transistor T3, and a gate of the fifth transistor T5 is connected to a light-emitting control signal terminal EM. A first electrode of the sixth transistor T6 is connected to the first electrode of the driving transistor T3, and a gate of the sixth transistor T6 is connected to a light-emitting control signal terminal EM. A first electrode of the seventh transistor T7 is connected to an initial signal terminal Vinit, a second electrode of the seventh transistor T7 is connected to a second electrode of the sixth transistor T6, and a gate of the seventh transistor T7 is connected to a reset signal terminal Re2. The capacitor C is connected between the gate of the driving transistor T3 and the first power terminal VDD. The pixel circuit 200 can be connected to a light-emitting device OLED for driving the light-emitting device OLED to emit light, with the light-emitting device OLED connected between the second electrode of the sixth transistor T6 and a second power terminal VSS.

The transistors used in all embodiments of the present disclosure can be thin-film transistors, field-effect transistors, or devices with similar characteristics. In this specification, the first electrode can be the drain, the second electrode can be the source, or the first electrode can be the source, and the second electrode can be the drain.

The gate driver circuit 201 is located on the side of the pixel circuit 200 in proximity to the peripheral area 12, and with the gate driver circuit 201 is at least partially located within the display area 11. The gate driver circuit 201 can be connected to the pixel circuit 200 to input gate driving signals to drive the light-emitting device 901 to emit light. It should be noted that the gate driver circuit 201 is at least partially located within the display area 11, which means that the gate driver circuit 201 may be located entirely within the display area 11, or may be partially within the display area 11 and partially within the peripheral area 12, without specific limitations in this disclosure.

As shown in FIG. 2, in some embodiments of the present disclosure, the display area 11 includes a main display area 111 and an auxiliary display area 112. The auxiliary display area 112 is located on a side of the main display area 111 in proximity to the peripheral area 12. An orthographic projection of the pixel circuit 200 on the substrate 1 is located within the main display area 111, and an orthographic projection of the gate driver circuit 201 on the substrate 1 is at least partially located within the auxiliary display area 112.

In some embodiments of the present disclosure, the driving circuit further includes a light-emitting control circuit 202. The light-emitting control circuit 202 is located on a side of the gate driver circuit 201 away from the pixel circuit 200, specifically in the peripheral area 12. The light-emitting control circuit 202 can be connected to the pixel circuit 200 to input light-emitting control signals, etc., to the pixel circuit 200. The pixel circuit 200, the gate driver circuit 201, and the light-emitting control circuit 202 may include multiple transistors, such as thin-film transistors.

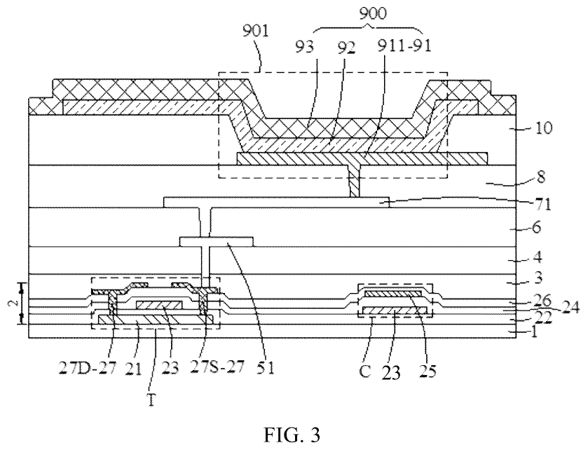

As shown in FIG. 3, in some embodiments of the present disclosure, the driving circuit layer 2 may consist of a multi-layer film structure. Taking thin-film transistors with top-gate structure as an example, the driving circuit layer 2 includes an active layer 21, a first gate insulation layer 22, a first gate metal layer 23, a second gate insulation layer 24, a second gate metal layer 25, an interlayer dielectric layer 26, and a first source and drain layer 27.

The active layer 21 is disposed on a side of the substrate 1. The first gate insulation layer 22 is disposed on a side of the active layer 21 away from the substrate 1, covering the active layer 21. The first gate metal layer 23 is disposed on a side of the first gate insulation layer 22 away from the substrate 1 and is used to form a first electrode plate of the capacitor C and the gate of the transistor T. The second gate insulation layer 24 is disposed on a side of the first gate metal layer 23 away from the substrate 1, covering the first gate metal layer 23. The second gate metal layer 25 is disposed on a side of the first gate insulation layer 22 away from the substrate 1, disposed opposite to the first electrode plate, and is used to form a second electrode plate of the capacitor C. The interlayer dielectric layer 26 is disposed on a side of the second gate metal layer 25 away from the substrate 1, covering the second gate metal layer 25. The first source and drain layer 27 is disposed on a side of the interlayer dielectric layer 26 away from the substrate 1 and is used to form the source 27S and drain 27D of the transistor, with the source 27S and drain 27D connected to the active layer 21.

In some embodiments of the present disclosure, the display panel further includes a pixel definition layer 10 and a light-emitting device layer 900. The light-emitting device layer 900 includes a plurality of light-emitting devices 901 located in the display area 11. There is a plurality of pixel circuits 200, and each pixel circuit 200 corresponds to driving one light-emitting device 901 to emit light.

The pixel definition layer 10 is disposed on a side of the driving circuit layer 2 away from the substrate 1. The pixel definition layer 10 includes a plurality of openings, and each opening defines the area of a light-emitting device 901. The shape of the opening, i.e., the shape of the contour of the orthographic projection, on the substrate 1, of the opening, can be polygonal, a smooth closed curve, or other shapes, without specific limitations.

Taking the light-emitting device 901 as the light-emitting device OLED for example, the light-emitting device layer 900 includes a first electrode layer 91, a light-emitting functional layer 92, and a second electrode layer 93 arranged sequentially in the direction away from the substrate 1. The first electrode layer 91 includes a plurality of first electrodes 911 spaced apart. Each opening in the pixel defining layer 10 corresponds to and exposes each of first electrodes 911, with each opening being no larger than its corresponding exposed first electrode 911. In other words, the area of any opening is located within the boundary of its corresponding first electrode 911. The light-emitting functional layer 92 covers the first electrodes 911, and the second electrode layer 93 covers the light-emitting functional layer 92. The first electrode 911 can be connected to the source/drain of the transistor in the pixel circuit 200. The first electrode layer 91 can be a single-layer or multi-layer structure, and its material can include one or more of: conductive metal, metal oxide, and alloy.

It should be noted that FIG. 3 only exemplifies the membrane layer structure of the display panel in the present disclosure in the display area 11, while the membrane layer structure of the peripheral area 12 and part of the display area 11 is referenced in FIGS. 4 to 7.

As shown in FIGS. 4 to 7, the first metal layer 50 is disposed on the side of the driving circuit layer 2 away from the substrate 1 and is insulated from the driving circuit layer 2. For ease of display, a simplified treatment of the specific membrane layer structure of the driving circuit layer 2 is shown in the figures. The driving circuit layer 2 includes a driving circuit, which includes the pixel circuit 200, the gate driver circuit 201, and the light-emitting control circuit 202. FIGS. 4 to 7 only show the regions containing the gate driver circuit 201 and the light-emitting control circuit 202.

The orthographic projection of the first metal layer 50 on the substrate 1 overlaps at least partially with the orthographic projection of the gate driver circuit 201 on the substrate 1. That is, the first metal layer 50 is at least partially opposite the gate driver circuit 201. In some embodiments of the present disclosure, the first metal layer 50 is located partially in the display area 11 and partially in the peripheral area 12, and the orthographic projection of the first metal layer 50 on the substrate 1 does not overlap with the orthographic projection of the pixel circuit 200 on the substrate 1. The material of the first metal layer 50 can be a single layer or multi-layer of conductive metals or alloy materials, such as copper, aluminum, silver, etc., without specific limitations.

The first electrode layer 91 is disposed on the side of the first metal layer 50 away from the substrate 1 and is insulated from the first metal layer 50. The orthographic projection of the first electrode layer 91 on the substrate 1, the orthographic projection of the first metal layer 50 on the substrate 1, and the orthographic projection of the gate driver circuit 201 on the substrate 1 are at least partially overlapped. The pixel circuit 200 corresponds and is electrically connected to each first electrode 911 of the first electrode layer 91 to drive each light-emitting device 901 to emit light.

As shown in FIG. 1 and FIG. 9, in some embodiments, the first electrode 911 is connected to the second electrode of the sixth transistor T6 in the pixel circuit 200, i.e., connected to node N1. In actual structure, the first electrode 911 includes an electrical connection portion 911a, and the first electrode 911 is electrically connected in one-to-one correspondence with the pixel circuit 200 through the electrical connection portion 911a.

In related art, when a portion of the gate driver circuit 201 is set in the display area 11, the gate driver circuit 201 may affect the connection node, i.e. N1 node, between the first electrode 911 above it and the pixel circuit 200 due to the jitter of its internal transistor, thus affecting the display effect of the display panel.

To address this, the present disclosure provides the first metal layer 50 between the first electrode layer 91 and the gate driver circuit 201, which can shield the gate driver circuit 201, protecting the first electrode layer 91 and the light-emitting devices 901 containing the first electrode layer 91 from the influence of the gate driver circuit 201, thereby providing a structural foundation to ensure the display effect of the display panel.

To further explain the positional relationship between the various driving circuits in the present disclosure and the first metal layer 50 and the first electrode layer 91, further division of regions within the display area 11 is performed. As shown in FIG. 2, in some embodiments of the present disclosure, the display area 11 includes a main display area 111 and an auxiliary display area 112. The auxiliary display area 112 is located on a side of the main display area 111 in proximity to the peripheral area 12. The pixel circuit 200 is located in the main display area 111, and the gate driver circuit 201 is at least partially located in the auxiliary display area 112. Correspondingly, the first metal layer 50 is also at least partially in the auxiliary display area 112.

A portion of the first electrode layer 91 corresponds to and is located in the auxiliary display area 112, and a portion of the first electrode layer 91 corresponds to and is located in the main display area 111. It should be noted that all first electrodes 911 in the first electrode layer 91 are electrically connected in one-to-one correspondence with the pixel circuits 200 located in the main display area 111. That is, the first electrodes 911 in the main display area 111 and the first electrodes 911 in the auxiliary display area 112 are electrically connected one-to-one to the pixel circuit 200 located in the main display area 111. Therefore, the light-emitting devices 901 in the auxiliary display area 112 and the light-emitting devices 901 in the main display area 111 can both be driven to emit light by the pixel circuits 200.

An orthographic projection, on the substrate 1, of the electrical connection portion 911a of the first electrode 911 in the auxiliary display area 112, is within the orthographic projection of the first metal layer 50 on the substrate 1. In this embodiment, the first metal layer 50 shields the electrical connection portion 911a of the first electrode 911 from the gate driver circuit 201, effectively avoiding jittering or fluctuation at the connection node between the first electrode 911 and the pixel circuit 200, such as node N1 shown in FIG. 1, thereby helping to ensure the display quality of the display panel. Furthermore, to enhance the shielding effect, the orthographic projection, on the substrate, of the first electrode layer 91 in the auxiliary display area 112 is within the orthographic projection of the first metal layer 50 on the substrate.

In the present disclosure, by reducing the size of the pixel circuit 200, the occupied area of the pixel circuit 200 in the display area 11 is reduced to leave some space for setting the gate driver circuit 201. It should be noted that reducing the size of the pixel circuit 200 specifically refers to reducing the size of some pixel circuits 200 or reducing the size of all pixel circuits 200, without specific limitations.

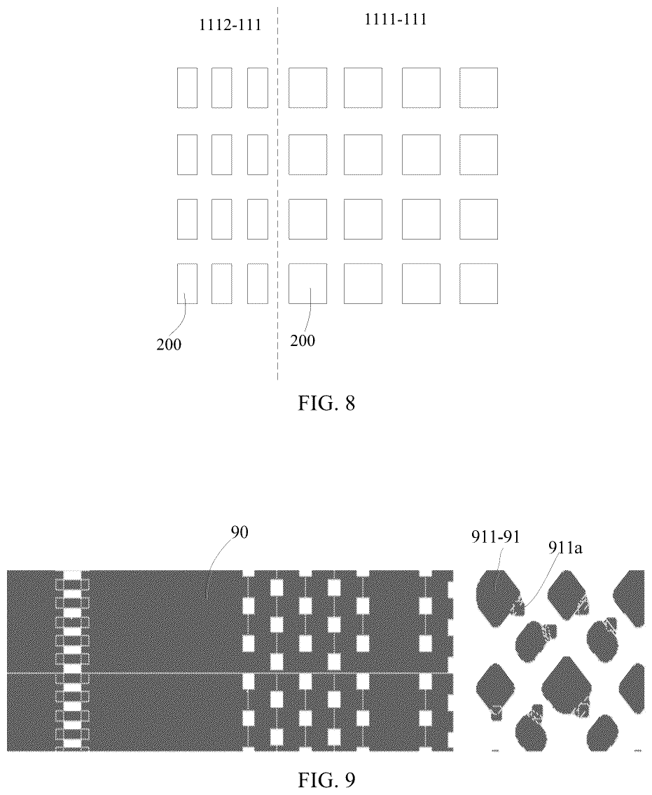

As shown in FIG. 2 and FIG. 8, taking the reduction of the size of some pixel circuits 200 as an example, in some embodiments of the present disclosure, the main display area 111 includes a central area 1111 and an edge area 1112, with the edge area 1112 located on a side of the central area 1111 in proximity to the auxiliary display area 112. In the pixel circuits 200 located in the edge area 1112, at least one column of pixel circuits 200 has a smaller size in the direction parallel to the display area 11 towards the peripheral area 12 compared to the pixel circuits 200 located in the central area 1111. There may be one or more columns of pixel circuits 200 in the edge area 1112 with a size smaller than the pixel circuits 200 in the central area 1111, which can be set according to actual conditions.

As shown in FIGS. 3, 4 to 7, in some embodiments of the present disclosure, the display panel further includes a first power line L, located between the substrate 1 and the first metal layer 50 in the peripheral area 12. The first power line L can be used to provide the second power voltage Vss.

The first power line L is electrically connected to the first metal layer 50, and the first metal layer 50 is electrically connected to the second electrode layer 93. In this embodiment, the first metal layer 50 is reused as a connection layer, or a bridging layer, or an intermediate layer to provide the second power voltage Vss to the second electrode layer 93. The second electrode layer 93 can be the cathode layer of the light-emitting devices 901.

The material of the first power line L can be a metal conductive material or an alloy conductive material. The first power line L can be disposed in the same layer with the source and drain of the transistor in the driving circuit. In the present disclosure, the source and drain of the transistor are not located on the active layer of the transistor. For example, the active layer of the transistor has a channel region, and a source contact region and a drain contact region on both sides of the channel region, and the source and the source contact region are overlapped and electrically connected, and the drain and the drain contact region are overlapped and electrically connected. Specifically, the first power line L may be disposed in the same layer with the first source and drain layer 27 of the driving circuit layer 2. In the present disclosure, “disposed in the same layer” means the same material and the same process are used for manufacture.

In related art, in order to achieve a narrower border design, the line width of the first power line L located in the peripheral area 12 is usually reduced. In this case, the first power line L may generate heat due to the narrower line width, posing a risk.

In the present disclosure, the first metal layer 50 is reused as a connection layer, or a bridging layer, or an intermediate layer, which achieves the shielding function, mentioned above, and at the same time increases the transmission area of the first power line L, thereby helping to avoid heating of the first power line L due to the narrower line width.

In some embodiments of the present disclosure, the first metal layer 50 is at least partially located in the peripheral area 12, and the orthographic projection of the first metal layer 50 on the substrate 1 at least partially overlaps with an orthographic projection of the first power line L on the substrate 1. An end of the first metal layer 50 is overlapped and connected to a surface of the first power line L away from the substrate 1. The size of the overlap and connection area between the first metal layer and the first power line can be set according to actual conditions, without specific limitations.

In some embodiments of the present disclosure, the display panel further includes a first planarization layer 4 located on the side of the driving circuit layer 2 away from the substrate 1. Furthermore, the display panel may also include a passivation layer 3 located between the driving circuit layer 2 and the first planarization layer 4. An orthographic projection of the passivation layer 3 on the substrate 1 can cover various driving circuits, such as the orthographic projections, on the substrate 1, of the light-emitting control circuit 202, the gate driver circuit 201, and the pixel circuit 200.

The first planarization layer 4 is located on a side of the passivation layer 3 away from the substrate 1. In some embodiments of the present disclosure, as shown in FIG. 4, the first flattening layer 4 includes a first segment 41 and a second segment 42 arranged in sequence and spaced apart. An orthographic projection of the first segment 41 on the substrate 1 at least partially overlaps with the orthographic projection of the light-emitting control circuit 202 on the substrate 1, and the orthographic projection of the first segment 41 on the substrate 1 does not overlap with the orthographic projection of the gate driver circuit 201 on the substrate 1. That is, the first segment 41 is located in the peripheral area 12. An orthographic projection of the second segment 42 on the substrate 1 at least partially overlaps with the orthographic projection of the gate driver circuit 201 on the substrate 1, and the orthographic projection of the second segment 42 on the substrate 1 does not overlap with the orthographic projection of the light-emitting control circuit 202 on the substrate 1. In this embodiment, the second segment 42 can be entirely located in the display area 11, or partially in the display area 11 and partially in the peripheral area 12. An orthographic projection, on the substrate 1, of the portion of the second segment 42 located in the display area 11, may partially overlap with the orthographic projection of the pixel circuit 200 on the substrate 1.

The materials of the passivation layer 3 and the first planarization layer 4 can be organic materials or other insulating materials. In this embodiment, the first planarization layer 4 includes the first segment 41 and the second segment 42 spaced apart. The first segment 41 is located in the peripheral area 12, and there is a gap between the first segment 41 and the second segment 42, which effectively helps block external moisture and other influences on the various pixel circuits 200 or light-emitting devices 901 located in the display area 11, enhancing the moisture-proof and waterproof effect of the display panel. The thickness of the passivation layer 3 and the first planarization layer 4 can be set according to actual conditions. Generally, the thickness of the first planarization layer 4 is greater than the thickness of the passivation layer 3.

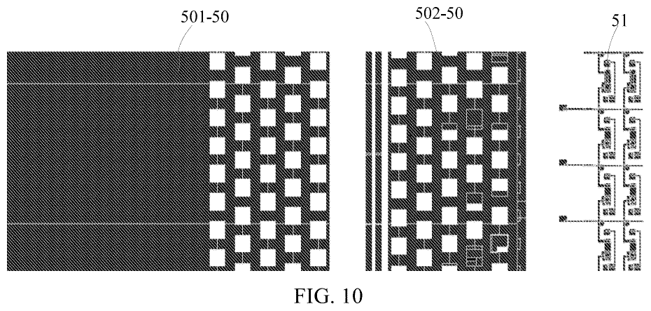

As shown in FIG. 4 and FIG. 10, in some embodiments of the present disclosure, the first metal layer 50 includes a first metal segment 501 and a second metal segment 502 spaced apart. The first metal segment 501 at least partially covers a surface of the first segment 41 away from the substrate 1, the second metal segment 502 at least partially covers a surface of the second segment 42 away from the substrate 1, and an orthographic projection of the first metal segment 501 on the substrate 1 and an orthographic projection of the second metal segment 502 on the substrate 1, do not located within a gap between the orthographic projection of the first segment 41 on the substrate 1 and the orthographic projection of the second segment 42 on the substrate 1. In this embodiment, the first metal layer 50 is partitioned into the first metal segment 501 and the second metal segment 502, where the orthographic projection of the first metal segment 501 on the substrate 1, does not located between the orthographic projection of the first segment 41 on the substrate 1 and the orthographic projection of the second segment 42 on the substrate 1, and the orthographic projection of the second metal segment 502 on the substrate 1, does not located between the orthographic projection of the first segment 41 on the substrate 1 and the orthographic projection of the second segment 42 on the substrate 1. This design helps reduce the risk of breakage and damage of the first metal layer 50 within the gap between the first segment 41 and the second segment 42. Of course, the first metal layer 50 can also be left unsegmented, without specific limitations.

As shown in FIG. 5, in some other embodiments of the present disclosure, the first planarization layer 4 also includes a third segment 43 located between the first segment 41 and the second segment 42. The first segment 41, the third segment 43, and the second segment 42 are spaced apart from each other. An orthographic projection of the third segment 43 on the substrate 1 is between the orthographic projection of the light-emitting control circuit 202 on the substrate 1 and the orthographic projection of the gate driver circuit 201 on the substrate 1. In this embodiment, the third segment 43 not only helps further enhance the moisture-proof and waterproof effect of the display panel, but also prevents breakage and damage of the various metal layers or other conductive layers located above it due to excessive height differences.

As shown in FIGS. 3, 4 to 7, in some embodiments of the present disclosure, the display panel also includes a second source and drain layer 51 disposed on the side of the driving circuit layer 2 away from the substrate 1, specifically disposed on a side of the first planarization layer 4 away from the substrate 1. The second source and drain layer 51 can be connected to the first source and drain layer 27 through via holes, i.e., connected to the source/drain of the transistor. The first metal layer 50 is disposed in the same layer with the second source and drain layer 51. Furthermore, as shown in FIG. 10, holes can be set on the first metal layer 50 and the second source and drain layer 51 to provide venting channels for the passivation layer 3 and the first planarization layer 4.

In some embodiments of the present disclosure, the transmission area of the first power line L can be increased by adding a new connection layer, bridging layer, or intermediate layer between the first metal layer 50 and the second electrode layer 93.

The above solution for adding a new connection layer, bridging layer, or intermediate layer will be described in detail below in connection with different embodiments.

As shown in FIGS. 3 and 4, in one embodiment of the present disclosure, the display panel further includes a first connection layer 90 (or a first bridging layer 90 or a first intermediate layer 90) disposed between the first metal layer 50 and the second electrode layer 93. An orthographic projection of the first connection layer 90 on the substrate 1 at least partially overlaps with the orthographic projection of the first metal layer 50 on the substrate 1. The first connection layer 90 may partially be located in the peripheral area 12 and partially in the display area 11. The first metal layer 50 is electrically connected to the second electrode layer 93 through the first connection layer 90.

The material of the first connection layer 90 can include metal materials or alloy materials to ensure good conductivity. Of course, the first connection layer 90 can also use transparent conductive materials, such as indium tin oxide (ITO), indium zinc oxide (IZO), etc. Specifically, the first connection layer 90 can be disposed in the same layer with the first electrode layer 91. In this embodiment, the transmission area of the first power line L is further increased through the first connection layer 90. Additionally, by disposing the first connection layer 90 in the same layer with the first electrode layer 91, this scheme effectively increases the transmission area of the first power line L without adding complexity to the production process, avoiding overheating due to the reduced line width of the first power line L.

In this embodiment, the display panel also includes a second planarization layer 6 disposed between the first metal layer 50 and the first connection layer 90. The second planarization layer 6 includes a fourth segment 61 and a fifth segment 62 spaced apart.

An orthographic projection of the fourth segment 61 on the substrate 1 at least partially overlaps with the orthographic projection of the light-emitting control circuit 202 on the substrate 1, and the orthographic projection of the fourth segment 61 on the substrate 1 does not overlap with the orthographic projection of the gate driver circuit 201 on the substrate 1. That is, the fourth segment 61 is located in the peripheral area 12. An orthographic projection of the fifth segment 62 on the substrate 1 at least partially overlaps with the orthographic projection of the gate driver circuit 201 on the substrate 1, and the orthographic projection of the fifth segment 62 on the substrate 1 does not overlap with the orthographic projection of the light-emitting control circuit 202 on the substrate 1. In this embodiment, the fifth segment 62 may be entirely located in the display area 11, or partially in the display area 11 and partially in the peripheral area 12. The orthographic projection, on the substrate 1, of the portion of the fifth segment 62 located in the display area 11, may partially overlap with the orthographic projection of the pixel circuit 200 on the substrate 1.

The material of the second planarization layer 6 can be an organic material or other insulating material. In this embodiment, the second planarization layer 6 includes the fourth segment 61 and the fifth segment 62 spaced apart. The fourth segment 61 is located in the peripheral area 12, and there is a gap between the fourth segment 61 and the fifth segment 62, which can further help block external moisture and other influences on the various pixel circuits 200 or light-emitting devices 901 located in the display area 11, enhancing the moisture-proof and waterproof effect of the display panel.

As shown in FIG. 3, the display panel also includes a first conductive layer 71 disposed between the second source and drain layer 51 and the first electrode layer 91. The first electrode layer 91 can be connected to the first source and drain layer 27 through the first conductive layer 71 and the second source and drain layer 51, i.e., connected to the source and drain of the transistor in the pixel circuit 200. Some areas of the second planarization layer 6 are located between the first conductive layer 71 and the second source and drain layer 51. The material of the first conductive layer 71 can include metal materials or alloy materials to ensure good conductivity. Additionally, the first conductive layer 71 can also use transparent conductive materials such as indium tin oxide (ITO), indium zinc oxide (IZO), etc.

The first conductive layer 71 is located in the display area 11, and an insulation layer can be disposed between the first conductive layer 71 and the first electrode layer 91. The first electrode layer 91, the first conductive layer 71, the second source and drain layer 51, and the first source and drain layer 27 are connected through via holes.

It should be noted that the display panel may also not include the first conductive layer 71. In this case, the first electrode layer 91 can be connected to the first source and drain layer 27 through the second source and drain layer 51.

As shown in FIGS. 3, 6, and 7, in some other embodiments of the present disclosure, the display panel also includes a second connection layer 70 (or a second bridging layer 70 or a second intermediate layer 70) disposed between the first metal layer 50 and the first connection layer 90, electrically connected to the first metal layer 50, and electrically connected to the first connection layer 90. The second connection layer 70 may partially be located in the peripheral area 12 and partially in the display area 11. The second connection layer 70 can be disposed in the same layer with the first conductive layer 71.

The material of the second connection layer 70 can include a metal material or an alloy material to ensure good conductivity. Additionally, the second connection layer 70 can also use transparent conductive materials such as indium tin oxide (ITO), indium zinc oxide (IZO), etc. In this embodiment, the transmission area of the first power line L is further increased by the second connection layer 70.

As shown in FIG. 4 and FIG. 5, in the present disclosure, when the display panel includes the first connection layer 90 and does not include the second connection layer 70, the second planarization layer 6 is disposed on the side away from the substrate 1 of the first metal layer 50 and the second source and drain layer 51.

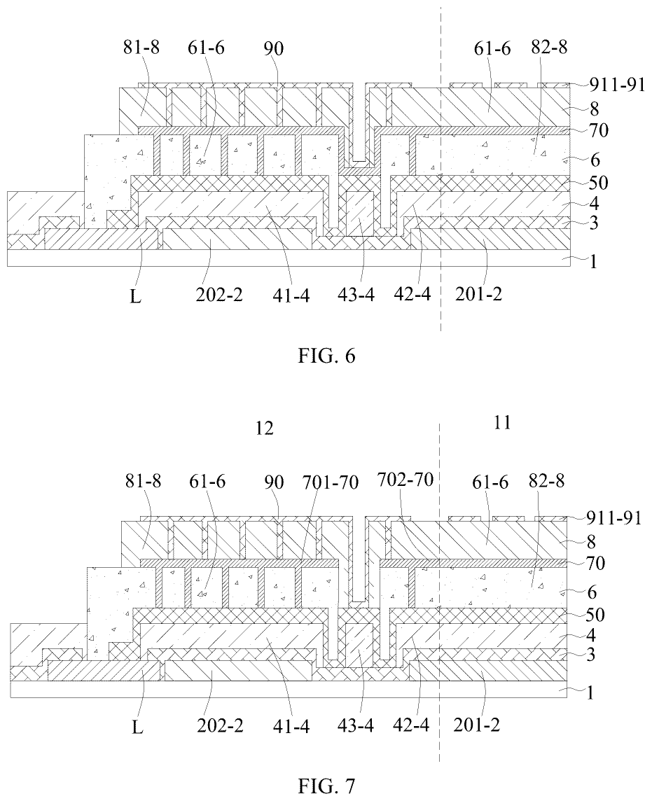

As shown in FIG. 6 and FIG. 7, when the display panel includes both the first connection layer 90 and the second connection layer 70, the second planarization layer 6 is located between the first metal layer 50 and the second connection layer 70. In this case, the display panel also includes a third planarization layer 8. The third planarization layer 8 is disposed between the second connection layer 70 and the first connection layer 90. The third planarization layer 8 includes a sixth segment 81 and a seventh segment 82 arranged in sequence and spaced apart. An orthographic projection of the sixth segment 81 on the substrate 1 at least partially overlaps with the orthographic projection of the light-emitting control circuit 202 on the substrate 1, and the orthographic projection of the sixth segment 81 on the substrate 1 does not overlap with the orthographic projection of the gate driver circuit 201 on the substrate 1. That is, the sixth segment 81 is located in the peripheral area 12. An orthographic projection of the seventh segment 82 on the substrate 1 at least partially overlaps with the orthographic projection of the gate driver circuit 201 on the substrate, and the orthographic projection of the seventh segment 82 on the substrate 1 does not overlap with the orthographic projection of the light-emitting control circuit 202 on the substrate 1. In this embodiment, the seventh segment 82 may be entirely located in the display area 11, or partially in the display area 11 and partially in the peripheral area 12. An orthographic projection, on the substrate 1, of the portion of the seventh segment 82 located in the display area 11, may partially overlap with the orthographic projection of the pixel circuit 200 on the substrate 1.

The material of the third planarization layer 8 can be an organic material or other insulating materials. In this embodiment, the third planarization layer 8 includes the sixth segment 81 and the seventh segment 82 spaced apart. The sixth segment 81 is located in the peripheral area 12, and there is a gap between the sixth segment 81 and the seventh segment 82, which can further help block external moisture and other influences on the various pixel circuits 200 or light-emitting devices 901 located in the display area 11, enhancing the moisture-proof and waterproof effect of the display panel. The third planarization layer 8 can be reused as an insulation layer disposed between the first conductive layer 71 and the first electrode layer 91 in the embodiments mentioned above.

In some embodiments of the present disclosure, via holes can be set on the second connection layer 70 and the first connection layer 90 to provide venting channels for the third planarization layer 8 and the second planarization layer 6. Similarly, via holes can also be set on the first electrode layer 91.

As shown in FIG. 7, in some embodiments of the present disclosure, the second connection layer 70 includes a first connection segment 701 and a second connection segment 702 spaced apart. The first connection segment 701 at least partially covers a surface of the sixth segment 81 away from the substrate 1, and the second connection segment 702 at least partially covers a surface of the seventh segment 82 away from the substrate 1. An orthographic projection of the first connection segment 701 on the substrate 1 and an orthographic projection of the second connection segment 702 on the substrate 1, do not located within a gap between the orthographic projection of the sixth segment 81 on the substrate 1 and the orthographic projection of the seventh segment 82 on the substrate 1. In this embodiment, the second connection layer 70 is partitioned into the first connection segment 701 and the second connection segment 702, where the orthographic projection of the first connection segment 701 on the substrate 1, does not located between the orthographic projection of the sixth segment 81 on the substrate 1 and the orthographic projection of the seventh segment 82 on the substrate 1, and the orthographic projection of the second connection segment 702 on the substrate 1, does not located between the orthographic projection of the sixth segment 81 on the substrate 1 and the orthographic projection of the seventh segment 82 on the substrate 1. This design helps reduce the risk of breakage and damage of the second connection layer 70 within the gap between the sixth segment 81 and the seventh segment 82. Of course, the second connection layer 70 can also be left unsegmented, without specific limitations.

The present disclosure also provides a method for manufacturing a display panel, including the following steps.
Step S100, providing a substrate 1, where the substrate 1 includes a display area 11 and a peripheral area 12 around the display area 11.
Step S200, forming a driving circuit layer 2 on a side of the substrate 1, where the driving circuit layer 2 includes a driving circuit; the driving circuit includes a gate driver circuit 201 and a pixel circuit 200; and the pixel circuit 200 is located in the display area 11, and the gate driver circuit 201 is located on a side of the pixel circuit 200 in proximity to the peripheral area 12 and at least partially located in the display area 11.
Step S300, forming a first metal layer 50 on a side of the driving circuit layer 2 away from the substrate 1, where the first metal layer 50 is insulated from the driving circuit layer 2.
Step S400, forming a first electrode layer 91 on a side of the first metal layer 50 away from the substrate 1, where the first electrode layer 91 is insulated from the first metal layer 50, located in the display area 11, and electrically connected to the pixel circuit 200. Orthographic projections, on the substrate 1, of the first electrode layer 91, the first metal layer 50, and the gate driver circuit 201 are at least partially overlapped.

The present disclosure further provides a display device including a display panel as described in any of the above embodiments. The specific structure and beneficial effects of the display panel can be referred to in the embodiments of the display panel mentioned above, and will not be repeated here. The display device of the present disclosure can be a mobile phone, tablet, TV, or other electronic devices, without being limited to these examples.

Those skilled in the art will readily conceive of other embodiments of the present disclosure after considering the specification and practicing the invention disclosed here. The aim of this application is to cover any modifications, uses, or adaptations of the present disclosure following the general principles and including common knowledge or conventional technical means in the art that are not disclosed in the present disclosure. The specification and embodiments are exemplary, and the true scope and spirit of the present disclosure are indicated by the appended claims.

1. A display panel, comprising:
a substrate comprising a display area and a peripheral area around the display area;
a driving circuit layer on a side of the substrate, comprising a driving circuit, wherein the driving circuit comprises:
a pixel circuit in the display area, and
a gate driver circuit on a side of the pixel circuit in proximity to the peripheral area, and at least partially in the display area;
a first metal layer on a side of the driving circuit layer away from the substrate, insulated from the driving circuit layer; and
a light-emitting device layer on a side of the first metal layer away from the substrate, comprising:
a first electrode layer in the display area, insulated from the first metal layer, and electrically connected to the pixel circuit;
wherein an orthographic projection of the first electrode layer on the substrate, an orthographic projection of the first metal layer on the substrate, and an orthographic projection of the gate driver circuit on the substrate, are at least partially overlapped.

2. The display panel of claim 1, wherein the display area comprises: a main display area, and an auxiliary display area on a side of the main display area in proximity to the peripheral area;
wherein the pixel circuit is in the main display area, the gate driver circuit is at least partially in the auxiliary display area, and the first metal layer is at least partially in the auxiliary display area;
wherein the pixel circuit comprises a plurality of pixel circuits, the first electrode layer comprises a plurality of first electrodes, each first electrode of the plurality of first electrodes comprises an electrical connection portion, and each first electrode of the plurality of first electrodes is electrically connected to a corresponding pixel circuit through the electrical connection portion; and wherein an orthographic projection, on the substrate, of the electrical connection portion of the first electrode in the auxiliary display area, is within the orthographic projection of first metal layer on the substrate.

3. The display panel of claim 1, wherein the light-emitting device layer further comprises a light-emitting functional layer and a second electrode layer arranged in sequence on a side of the first electrode layer away from the substrate; and the display panel further comprises:
a first power line between the substrate and the first metal layer, in the peripheral area; and
wherein the first power line is electrically connected to the first metal layer, and the first metal layer is electrically connected to the second electrode layer.

4. The display panel of claim 3, wherein the orthographic projection of the first metal layer on the substrate at least partially overlaps with an orthographic projection of the first power line on the substrate; and
an end of the first metal layer is overlapped and connected to a surface of the first power line away from the substrate.

5. The display panel of claim 3, wherein the first power line is disposed in a same layer with a source and drain of a transistor in the driving circuit.

6. The display panel of claim 5, further comprising:
a first connection layer between the first metal layer and the second electrode layer, wherein an orthographic projection of the first connection layer on the substrate, at least partially overlaps with the orthographic projection of the first metal layer on the substrate, and the first metal layer is electrically connected to the second electrode layer through the first connection layer.

7. The display panel of claim 6, wherein the first connection layer is disposed in a same layer with the first electrode layer.

8. The display panel of claim 7, further comprising:
a second connection layer between the first metal layer and the first connection layer, wherein the second connection layer is electrically connected to the first metal layer and electrically connected to the first connection layer.

9. The display panel of claim 6, wherein the driving circuit layer further comprises:
a light-emitting control circuit between the first power line and the gate driver circuit, wherein the orthographic projection of the first metal layer on the substrate, at least partially overlaps with an orthographic projection of the light-emitting control circuit on the substrate.

10. The display panel of claim 9, further comprising:
a first planarization layer on the side of the driving circuit layer away from the substrate, comprising a first segment and a second segment arranged in sequence and spaced apart,
wherein an orthographic projection of the first segment on the substrate, at least partially overlaps with the orthographic projection of the light-emitting control circuit on the substrate, and an overlapping area, between the orthographic projection of the first segment on the substrate and the orthographic projection of the gate driver circuit on the substrate, is zero; and
wherein an orthographic projection of the second segment on the substrate, at least partially overlaps with the orthographic projection of the gate driver circuit on the substrate, and an overlapping area, between the orthographic projection of the second segment on the substrate and the orthographic projection of the light-emitting control circuit on the substrate, is zero.

11. The display panel of claim 10, wherein the first metal layer comprises a first metal segment and a second metal segment spaced apart; and
wherein the first metal segment at least partially covers a surface of the first segment away from the substrate, the second metal segment at least partially covers a surface of the second segment away from the substrate, and an orthographic projection of the first metal segment on the substrate and an orthographic projection of the second metal segment on the substrate, do not within a gap between the orthographic projection of the first segment on the substrate and the orthographic projection of the second segment on the substrate.

12. The display panel of claim 10, wherein the first planarization layer further comprises a third segment between the first segment and the second segment, with the first segment, third segment, and second segment being spaced apart from each other; and
wherein an orthographic projection of the third segment on the substrate, is between the orthographic projection of the light-emitting control circuit on the substrate and the orthographic projection of the gate driver circuit on the substrate.

13. The display panel of claim 10, further comprising:
a second planarization layer between the first metal layer and the first connection layer, comprising a fourth segment and a fifth segment arranged in sequence and spaced apart;
wherein an orthographic projection of the fourth segment on the substrate, at least partially overlaps with the orthographic projection of the light-emitting control circuit on the substrate, and an overlapping area, between the orthographic projection of the fourth segment on the substrate and the orthographic projection of the gate driver circuit on the substrate, is zero; and
wherein an orthographic projection of the fifth segment on the substrate, at least partially overlaps with the orthographic projection of the gate driver circuit on the substrate, and an overlapping area, between the orthographic projection of the fifth segment on the substrate and the orthographic projection of the light-emitting control circuit on the substrate, is zero.

14. The display panel of claim 13, wherein when the display panel further comprises a second connection layer, the second planarization layer is between the first metal layer and the second connection layer; and the display panel further comprises:
a third planarization layer between the second connection layer and the first connection layer, comprising a sixth segment and a seventh segment arranged in sequence and spaced apart;
wherein an orthographic projection of the sixth segment on the substrate, at least partially overlaps with the orthographic projection of the light-emitting control circuit on the substrate, and an overlapping area, between the orthographic projection of the sixth segment on the substrate and the orthographic projection of the gate driver circuit on the substrate, is zero; and
wherein an orthographic projection of the seventh segment on the substrate, at least partially overlaps with the orthographic projection of the gate driver circuit on the substrate, and an overlapping area, between the orthographic projection of the seventh segment on the substrate and the orthographic projection of the light-emitting control circuit on the substrate, is zero.

15. The display panel of claim 14, wherein when the display panel further comprises the second connection layer, the second connection layer comprises a first connection segment and a second connection segment spaced apart; and
wherein the first connection segment at least partially covers a surface of the sixth segment away from the substrate, the second connection segment at least partially covers a surface of the seventh segment away from the substrate, and an orthographic projection of the first connection segment on the substrate and an orthographic projection of the second connection segment on the substrate, do not within a gap between the orthographic projection of the sixth segment on the substrate and the orthographic projection of the seventh segment on the substrate.

16. The display panel of claim 10, wherein the driving circuit layer comprises:
an active layer on a side of the substrate;
a first gate insulation layer on a side of the active layer away from the substrate, covering the active layer;
a first gate metal layer on a side of the first gate insulation layer away from the substrate, configured to form a first electrode plate of a capacitor in the driving circuit, and a gate of a transistor in the driving circuit;
a second gate insulation layer on a side of the first gate metal layer away from the substrate, covering the first gate metal layer;
a second gate metal layer on the side of the first gate insulation layer away from the substrate, disposed opposite to the first electrode plate, and configured to form a second electrode plate of the capacitor in the driving circuit;
an interlayer dielectric layer on a side of the second gate metal layer away from the substrate, covering the second gate metal layer; and
a first source and drain layer on a side of the interlayer dielectric layer away from the substrate, configured to form a source and drain of the transistor in the driving circuit, with the source and drain connected to the active layer.

17. The display panel of claim 16, further comprising:
a passivation layer between the driving circuit layer and the first planarization layer; and
a second source and drain layer on a side of the first planarization layer away from the substrate;
wherein the first metal layer is disposed in a same layer with the second source and drain layer.

18. A method for manufacturing a display panel, comprising:
providing a substrate comprising a display area and a peripheral area around the display area;
forming a driving circuit layer on a side of the substrate, comprising a driving circuit, wherein the driving circuit comprises:
a pixel circuit in the display area, and
a gate driver circuit on a side of the pixel circuit in proximity to the peripheral area, and at least partially in the display area;
forming a first metal layer on a side of the driving circuit layer away from the substrate, the first metal layer being insulated from the driving circuit layer; and
forming a first electrode layer in the display area and on a side of the first metal layer away from the substrate, the first electrode layer being insulated from the first metal layer and electrically connected to the pixel circuit;
wherein an orthographic projection of the first electrode layer on the substrate, an orthographic projection of the first metal layer on the substrate, and an orthographic projection of the gate driver circuit on the substrate, are at least partially overlapped.

19. A display device comprising a display panel of claim 1.

20. The display panel of claim 8, wherein the driving circuit layer further comprises:
a light-emitting control circuit between the first power line and the gate driver circuit, wherein the orthographic projection of the first metal layer on the substrate, at least partially overlaps with an orthographic projection of the light-emitting control circuit on the substrate.
